(19) United States
(12) Patent Application Publication
(10) Pub. No.: US 2026/0300598 A1
(43) Pub. Date: Oct. 1, 2026

(54) INCREMENTAL TOPOLOGY SYNTHESIS FOR A NETWORK-ON-CHIP

(71) Applicant: ARTERIS, INC., Campbell, CA (US)

(72) Inventor: Amir CHARIF, Paris (FR)

(73) Assignee: ARTERIS, INC., Campbell, CA (US)

(21) Appl. No.: 19/095,082

(22) Filed: Mar. 31, 2025

(51) Int. Cl. G06F 30/392

(52) U.S. Cl. CPC G06F 30/392

(57) ABSTRACT

Designing a network on chip (NoC) includes loading a NoC topology; selecting a source in the topology and identifying multiple destinations to which the source will be connected; and incrementally adding new connections to the NoC topology, one connection at a time. Adding a new connection includes selecting a next destination; and adding to the topology a new valid shortest distance connection from the next destination to an existing connection in the topology.

### FIELD

The present technology is in the field of electronic computer aided design of electronic systems, and more specifically, to electronic topology synthesis of a network-on-chip.

### BACKGROUND

Network on a chip (NoC) technology is being used at many semiconductor companies to support an ever-increasing number of cores on a single chip and satisfy a demand for ever-increasing processing power related to artificial intelligence (AI) and other applications. A NoC is superior to old point-to-point connectivity by way of a more scalable communication architecture that makes use of packet transmissions.

During design of a NoC, a NoC topology is synthesized. The NoC topology refers to a general layout of components (e.g., network interface units, buffers, switches, firewalls, and adapters) and electrical connections between the components. The topology significantly influences latency and power consumption. It also affects network traffic distribution.

NoC topology synthesis may undergo many iterations until the topology satisfies certain criteria, such as width of buses, quality of service, and memory map.

### SUMMARY

In accordance with various embodiments and aspects herein, a computer-implemented method of designing a network on chip (NoC) includes loading a NoC topology; selecting a source in the topology and identifying multiple destinations to which the source will be connected; and incrementally adding new connections to the NoC topology, one connection at a time. Adding a new connection includes selecting a next destination; and adding to the topology a new valid shortest distance connection from the next destination to an existing connection in the topology.

In accordance with various embodiments and aspects herein, a computer system includes a processing unit; and computer memory encoded with code that, when executed by the processing unit, causes the computer system to load a network-on-chip (NoC) topology; select a source in the topology and identify multiple destinations to which the source will be connected; and incrementally add new connections to the NoC topology, one connection at a time. Adding a new connection includes selecting a next destination; and adding to the topology a new valid shortest distance connection from the next destination to an existing connection in the topology.

In accordance with various embodiments and aspects herein, a product includes computer-readable memory encoded with code that, when executed, causes a processing unit to load a network-on-chip (NoC) topology; select a source in the topology and identify multiple destinations to which the source will be connected; and incrementally add new connections to the NoC topology, one connection at a time. Adding a new connection includes selecting a next destination; and adding to the topology a new valid shortest distance connection from the next destination to an existing connection in the topology.

### BRIEF DESCRIPTION OF THE DRAWINGS

In order to understand the invention more fully, a reference is made to the accompanying drawings. The invention is described in accordance with the aspects and embodiments in the following description with reference to the drawings or figures (FIG.), in which like numbers represent the same or similar elements. Understanding that these drawings are not to be considered limitations in the scope of the invention, the presently described aspects and embodiments and the presently understood best mode of the invention are described with additional detail through the use of the accompanying drawings.

FIG. 1 shows certain features of an electronic system including a NoC.

FIG. 2 shows an overview of a NoC design process in accordance with various aspects and embodiments herein.

FIG. 3 shows an incremental topology synthesis method in accordance with various aspects and embodiments herein.

FIGS. 4A, 4B, 4C, 4D and 4E illustrate a simple example in which an initial topology is synthesized according to the method of FIG. 3.

FIG. 5 shows an incremental topology synthesis method with lookahead in accordance with various aspects and embodiments herein.

FIGS. 6A, 6B, 6C, and 6D illustrate a simple example in which an initial topology is synthesized according to the method of FIG. 5.

FIG. 7 shows a tree representation of a simple example of different routing options during incremental topology synthesis with lookahead in accordance with various aspects and embodiments herein.

FIG. 8 shows a switch and connection reduction method in accordance with various aspects and embodiments herein.

FIG. 9 shows a computer system including code for performing incremental topology synthesis in accordance with various aspects and embodiments herein.

### DETAILED DESCRIPTION

The following describes various examples of the present technology that illustrate various aspects and embodiments of the invention. Generally, examples can use the described aspects in any combination. All statements herein reciting principles, aspects, and embodiments as well as specific examples thereof, are intended to encompass both structural and functional equivalents thereof. The examples provided are intended as non-limiting examples. Additionally, it is intended that such equivalents include both currently known equivalents and equivalents developed in the future, i.e., any elements developed that perform the same function, regardless of structure.

It is noted that, as used herein, the singular forms “a,” “an” and “the” include plural referents unless the context clearly dictates otherwise. Reference throughout this specification to “one embodiment,” “an embodiment,” “certain embodiment,” “various embodiments,” or similar language means that a particular aspect, feature, structure, or characteristic described in connection with the embodiment is included in at least one embodiment of the invention.

Thus, appearances of the phrases “in one embodiment,” “in at least one embodiment,” “in an embodiment,” “in certain embodiments,” and similar language throughout this specification may, but do not necessarily, all refer to the same embodiment or similar embodiments. Furthermore, aspects and embodiments of the invention described herein are merely exemplary, and should not be construed as limiting of the scope or spirit of the invention as appreciated by those of ordinary skill in the art. The disclosed invention is effectively made or used in any embodiment that includes any novel aspect described herein. All statements herein reciting principles, aspects, and embodiments of the invention are intended to encompass both structural and functional equivalents thereof. It is intended that such equivalents include both currently known equivalents and equivalents developed in the future. Furthermore, to the extent that the terms “including”, “includes”, “having”, “has”, “with”, or variants thereof are used in either the detailed description and the claims, such terms are intended to be inclusive in a similar manner to the term “comprising.”

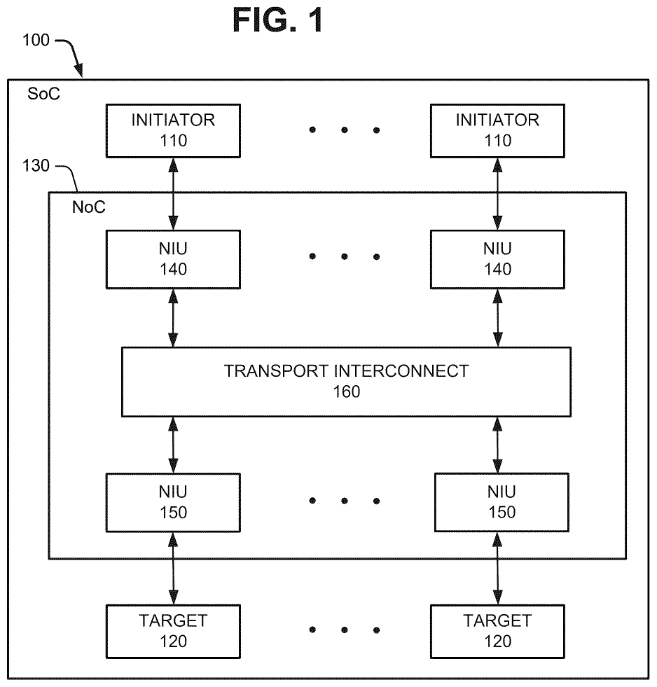

Reference is made to FIG. 1, which illustrates an electronic system. By way of example, the electronic system is a system-on-chip (SoC) 100. The SoC 100 includes a plurality of initiators 110 and targets 120. Examples of the initiators 110 include central processing units (CPUs), graphics processing units (GPUs), video cards, accelerators, and direct memory access (DMA) controllers. Examples of the targets 120 include volatile memory, persistent memory, and peripherals.

The SoC 100 further includes a network-on-chip (NoC) 130. The NoC 130 sends request transactions from an initiator 110 to one or more targets 120 using industry-standard protocols. A request transaction may include an address of the target 120. The NoC 130 decodes the address and transports the request transaction. The target 120 handles the request transaction and may send a response transaction, which is transported back to the initiator 110 via the NoC 130.

The NoC 130 includes a plurality of network interface units (NIUs) 140 and 150 and a transport interconnect 160. Those NIUs 140 that interface with initiators 110 are referred to as initiator NIUs 140, and those NIUs 150 that interface with targets 120 are referred to as target NIUs 150. Each initiator 110 is coupled to the transport interconnect 160 via a corresponding initiator NIU 140. Each target 120 is coupled to the transport interconnect 160 via a corresponding target NIU 150.

Each NIU 140 or 150 is configured to convert the protocol used by its corresponding initiator 110 or target 120 into a transport protocol used inside the NoC 130. The transport protocol is typically based on the transmission of packets.

The transport interconnect 160 includes switches, adapters, and buffers for transporting packets between the NIUs 140 and 150. Switches may be used to route flows of traffic between source and destinations. Adapters may be used to deal with various conversions between data width, clock and power domains. Buffers may be used to insert pipelining elements to span long distances, or to store packets to deal with rate adaptation between fast senders and slow receivers or vice-versa.

In general, the NoC 130 is highly configurable. Certain NoC components such as the NIUs 140 and 150 and switches may have many different possible configurations. Other NoC components such as buffers may have relatively fewer possible configurations.

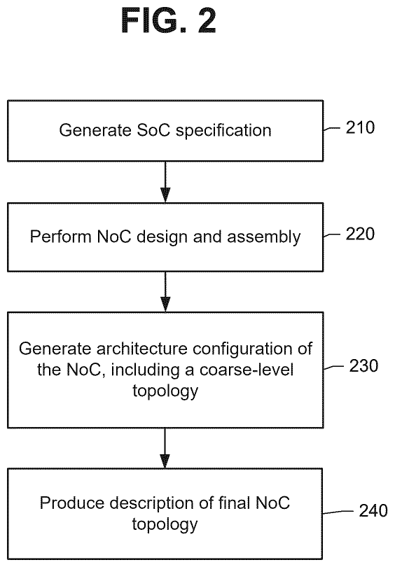

Reference is made to FIG. 2, which illustrates a general method of designing a NoC. At block 210, an SoC specification is generated. The specification provides a chip definition, technology, domains and layout for the system-on-chip (SoC). The specification also defines the real estate for the NoC and other NoC constraints. The SoC layout may include the locations of initiators and targets.

At block 220, NoC design and assembly are performed. Intellectual property (IP) blocks are selected from a NoC library, and the selected IP is instantiated. In addition, IP connection and assembly, sockets configuration, and end-to-performance capture may be performed. This stage produces a NoC specification that defines SoC IPs and their related sockets and protocols, along with the communication flows between initiators and targets, and memory maps.

At block 230, an architecture configuration of the NoC is generated. A coarse-level topology is generated in accordance with a method herein. Switches, buffers, firewalls, pipelines and rate adapters are added to the topology. Power, Performance and Area (PPA) tradeoffs may be performed (unit duplication is decided together with size of buffers in switches for example). A loop from block 230 back to block 220 helps in finalizing the architecture configuration by changing the settings of parameters, changing connectivity schemes (e.g., from a mesh to crossbar or modified mesh), enabling of safety through unit duplication, etc.

A NoC design may have to satisfy different performance requirements, such as connectivity and latency between source and destination, frequency of various elements, maximum area available for NoC logic and its associated routing (wiring), minimum throughput between sources and destinations, power consumption requirements, and position on the chip floorplan. Multiple iterations of the NoC topology may be generated until the different performance requirements are satisfied.

At block 240, a final NoC topology description is produced, for instance, in a computer-readable file or done through a user interface, in graphical or textual form. The description may be stored in computer memory, ready for use by software.

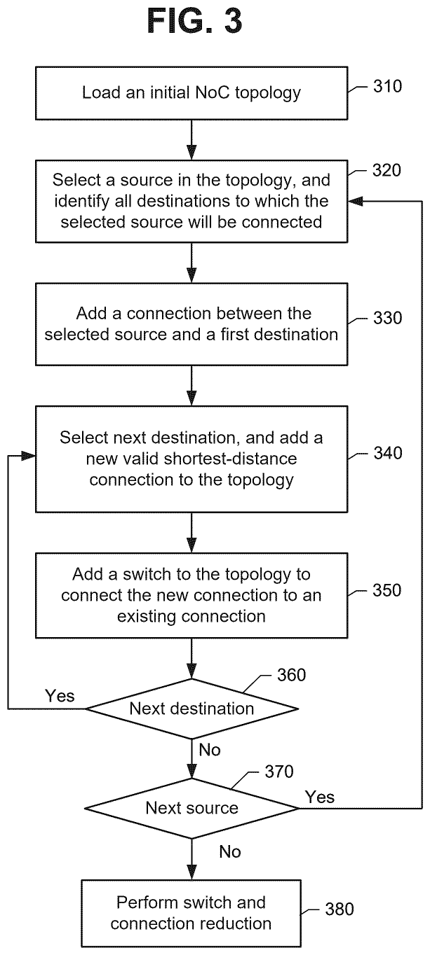

Reference is made to FIG. 3, which illustrates a method of automatically generating a coarse-level topology of a NoC. In general, electrical connections are made between sources and destinations to facilitate electrical communication between the sources and destinations. Each connection may include one or more wires. For example, a 32 bit connection between may include 32 individual wires in parallel. Routing of the connections may be rectilinear.

At block 310, an initial NoC topology is loaded. The initial NoC topology may include at least initiator ports and several target ports. The initial topology may also include NIUs at the initiator and target ports The initial topology may further include existing transport interconnect components (e.g., switches) and connections.

A source may include an initiator, and a destination may include a target. However, sources and destinations as used herein are not so limited. Sources and destination may include internal NoC elements. For example, if an existing NoC component will be rerouted, that existing component may be treated as a source or a destination.

User inputs and relevant information from the specification may also be loaded. For instance, the specification may identify all destinations to which each source will be connected.

At block 320, a source in the topology is selected, and all destinations to which the selected source will be connected are identified. A user input may specify the source that is selected, or the source may be selected automatically. The NoC specification may be used to identify the destinations. The destinations may be ordered. Let N be the total number of destinations, and let D={D1, . . . , DN} be the set of destinations after ordering. As a first example, the ordering is specified by a user input. As a second example, the destinations are sorted by distance from the selected source. The distances may be straight-line distances.

At block 330, a connection between the selected source and the first destination D1 is added to the topology.

At block 340, the next destination in set D is selected, and a new connection is added to the topology. The new connection is a new shortest valid connection from the selected destination to an existing connection in the topology. A new connection is considered valid if it follows constraints, is deadlock free, etc. A deadlock refers to a state that can arise when nodes along a path are in a circular “wait” and prevent each other from accessing the resources and from transmitting messages.

At block 350, a switch is added to the topology to connect the new connection to the existing connection. For example, the existing connection may be split into sub-connections, and the switch is inserted and coupled to the sub-connections and the new connection.

The functions at blocks 340 and 350 are automatically repeated until all of the destinations in set D have been connected to the selected source (block 360). In the alternative, a user input may specify the next destination, and the functions at blocks 340 and 350 are repeated for the specified destination.

If another source is selected (block 370), control is returned to block 320. The selection may be made automatically or by user inputs.

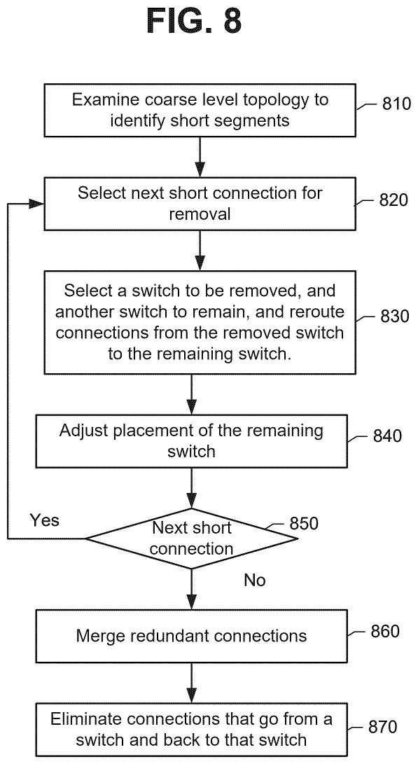

At block 380, the topology may be further refined by reducing the number of switches and connections. An example of a reduction method is illustrated in FIG. 8. Another example is described in assignee's U.S. Pat. No. 11,655,776.

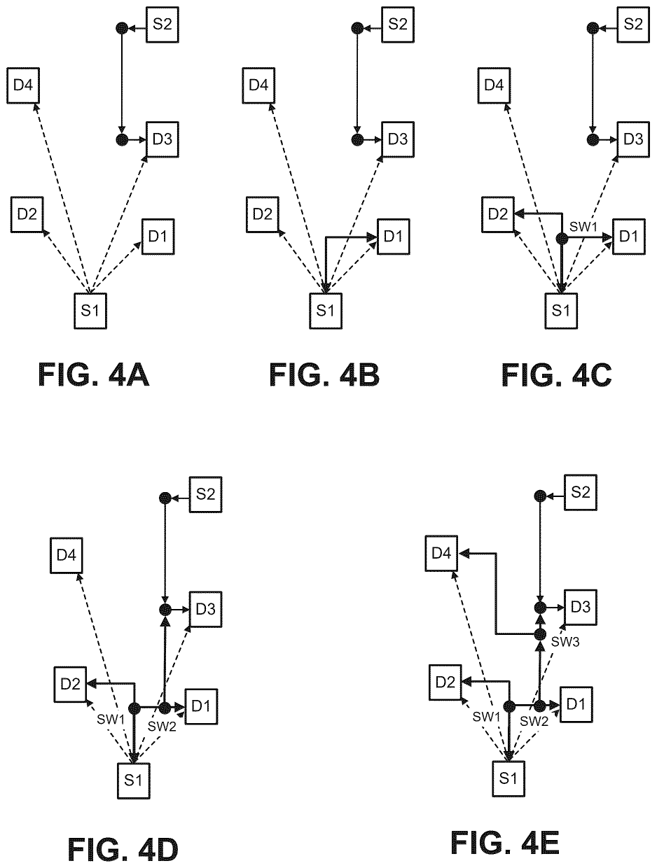

FIGS. 4A, 4B, 4C, 4D and 4E illustrate a simple example in which an initial topology is incrementally synthesized according to blocks 310-370 of the method of FIG. 3. FIG. 4A shows an initial NoC topology that is loaded: a source S1, and a set D of four destinations in the following order: a first destination D1, a second destination D2, a third destination D3 and a fourth destination D4. The initial topology also has existing components from an earlier topology: a second source S2 that is already connected to the third destination D3 by a connection S2-D3. The method of FIG. 3 will be used to connect the first source S1 to the first, second, third and fourth destinations D1, D2, D3 and D4.

FIG. 4B shows the NoC topology after a first incremental modification. A first connection from the first source S1 to first destination D1 is added to the topology.

FIG. 4C shows the NoC topology after a second incremental modification. The second destination D2 is selected for the next connection. A second connection connecting the second destination D2 to the first connection is added to the topology such that the second connection follows the shortest valid path to the first connection. A switch SW1 is added to the topology to connect the second connection to the first connection.

FIG. 4D shows the NoC topology after a third incremental modification. The third destination D3 is selected for the next connection. A third connection and a second switch SW2 are added to the topology. The third connection connects the third destination D3 to the first connection via the second switch SW2. The third connection extends along the shortest valid path.

FIG. 4E shows the NoC topology after a fourth incremental modification. The fourth destination D4 is the last destination in set D. A fourth connection connects the fourth destination D4 to the third connection via a third switch SW3.

Thus, the method of FIG. 3 automatically modifies the NoC topology, one connection at a time. This reduces processing burden and reduces the time to generate a NoC architecture configuration.

The method creates the fewest connections at the time a selected source is connected to a selected destination. For example, when connecting the first source S1 to the third destination D3, the chosen configuration is one that creates the least extra connections at the time the connections are added to the topology. The fourth connection that connects the first source S1 to the fourth destination D4 deviates quite a bit from a dedicated connection that goes straight to the fourth destination. The deviation could be minimized, but at the cost of creating more connections.

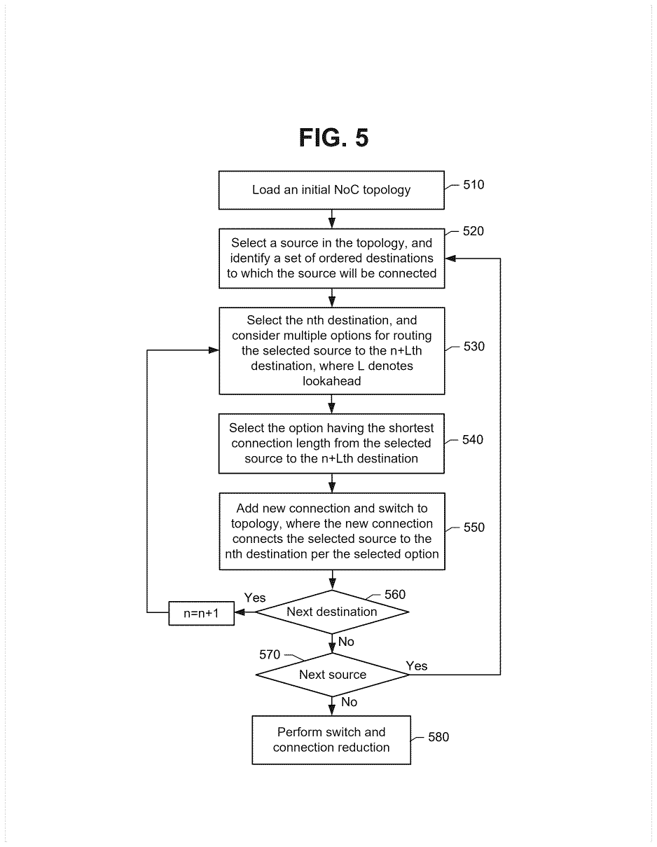

FIG. 5 illustrates another method of automatically generating a coarse-level NoC topology. Unlike the method of FIG. 3, the method of FIG. 5 considers not only the shortest valid path of a new connection being added, but it also looks ahead and considers how the new connection will affect at least one additional connection that will be added afterwards. There might be more than one option for adding an additional connection. Where there are multiple options, the method of FIG. 5 considers total valid connection length of each option, and selects the option having the shortest distance.

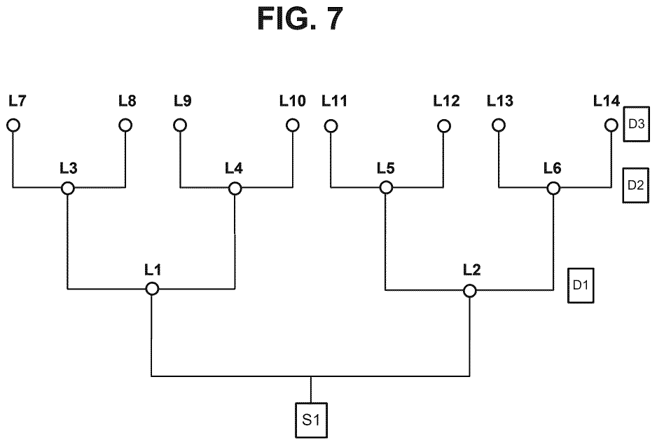

Before describing the method of FIG. 5, reference is made to FIG. 7, which illustrates a simple example of possible connections from a selected source S1 to each destination D1, D2, D3 in set D. Each connection is represented as a branch and has a valid connection length. In this simple example, there are two possible connections from the selected source to the first destination D1, two possible connections from the first destination D1 to the second destination D2 for each first-level branch, and two possible connections from the second destination D2 to the third destination D3 for each second-level branch.

If no lookahead is performed, only two options L1 and L2 will be considered, and the option with the shortest valid connection length from the selected source S1 to the first destination D1 will be selected. If a lookahead of one is used, four options L3, L4, L5 and L6 will be considered, and the option with the shortest valid connection length from the selected source S1 to the second destination D2 will be selected. However, only the connection from S1 to D1 in the selected option will be added to the NoC topology.

If a lookahead of two is used, eight options L7, L8, L9, L10, L11, L12, L13 and L4 will be considered, and the option with the shortest valid connection length from S1 to D3 will be selected. However, only the connection from S1 to D1 in the selected option will be added to the NoC topology.

Reference is now made to FIG. 5. At block 510, an initial topology is loaded. At block 520, a source is selected, and a set D of ordered destinations is identified.

At block 530, the n^{th} destination is selected, and multiple options for routing the selected source to the n+L^{th} destination are considered, where L denotes the lookahead.

At block 540, the option having the shortest valid connection length from the selected source to the n+L^{th} destination is selected.

At block 550, a new connection is added to the topology. The new connection connects the selected source to the n^{th} destination per the selected option. If the new connection is from S1 to D1, the new connection will be made directly to the selected source S1 and the first destination D1. For all subsequent connections, the new connection will be made from the n^{th} destination to an existing connection in the topology. Any switches for connecting the new connection to an existing connection are also added to the topology.

At block 560, if there is another destination in set D, control is returned to block 530. Otherwise, control is sent to block 570.

At block 570, if there is another source to be selected, control is returned to block 520. Otherwise, switch and connection reduction may be performed at block 580.

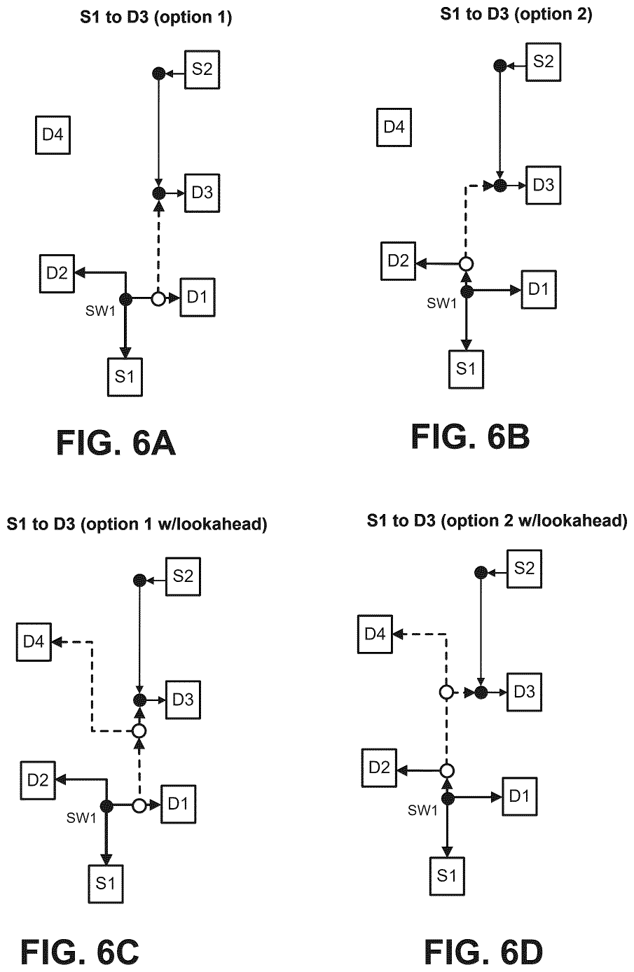

FIGS. 6A, 6B, 6C, and 6D illustrate a simple example that loads the topology of FIG. 4A and makes incremental modifications with a lookahead of L=1 according to the method of FIG. 5. First and second incremental modifications are made (but not shown) to connect the selected source S1 to the first and second destinations D1 and D2. FIGS. 6A to 6D will now illustrate a third incremental modification that connects the third destination with a lookahead of L=1.

FIGS. 6A and 6B shows first and second options, respectively, for connecting the third destination D3. The first option proposes the same route as FIG. 4C. The second option proposes a route that is closer to the fourth destination D4.

FIGS. 6C and 6D show the first and second options, respectively, with lookahead to the fourth destination D4. Possible connections to the fourth destination D4 are shown in dash. The connection to the fourth destination D4 in FIG. 6D (option 2) traverses a shorter distances than the connection to the fourth destination D4 in FIG. 6C (option 1). Therefore, the second option is selected. The connection to D3 from option 2 is added to the topology. A switch is also added to connect the new connection to the nearest existing connection.

The example of FIGS. 6A-6D illustrate a lookahead of one destination. However, the number of lookahead destinations is configurable. A larger number of lookahead destinations will have a greater number of options and will take longer to process for each incremental modification, but the resulting topology will likely be more accurate.

The methods of FIGS. 3 and 5 produce coarse-level topologies quickly and accurately without switch and connection reduction. However, accuracy may be further improved by reducing switches and connections in accordance with the method of FIG. 8.

Reference is made to FIG. 8, which illustrates a method of reducing switches and connections in a coarse-level topology. A first phase of the method includes identifying and removing short connections. A connection may be considered “short” if its length is less than a user-defined distance threshold.

The first phase is performed in blocks 810-850. At block 810, the coarse-level topology is examined to identify short connections between switches. At block 820, the next short connection is selected for removal. The selected short connection is between two switches.

At block 830, one of the two switches is selected to be removed, and the other of the two switches is selected to remain. Connections extending from the removed switch are rerouted to extend from the remaining switch. Connections routed to the removed switch are rerouted to the remaining switch. A connection going from the removed switch to the remaining switch is rerouted to the remaining switch. This is done to preserve the number of connections and thereby keep dependencies between connections intact.

At block 840, the placement of the remaining switch is adjusted. A position that minimizes the length of all connections to the remaining switch is desirable.

If any other short connections are identified for removal (block 850), control is returned to block 820. Otherwise, a second phase of the reduction method is performed.

The second phase includes merging redundant connections. Redundancy could result from removing switches during the first phase. Redundant connections include connections that are routed from a switch to itself. Redundant connections also include multiple connections between the same two switches. For example, three segments going from a first switch to a second switch would be considered redundant.

The second phase is performed in blocks 860 and 870. During this second phase, no new connection dependencies are introduced, and it is ensured that no new deadlocks and no new traffic class (separation) violations are introduced. A traffic class refers to a way of physically separating certain traffic (source-destination pairs) from each other. When redundant connections are merged, traffics of two different traffic classes should not be merged.

At block 860, redundant connections are identified in the coarse-level topology and merged into a single connection. At block 870, connections going from a switch to itself may be eliminated.

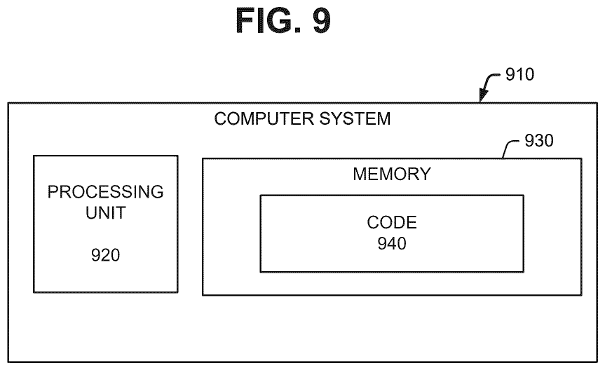

Reference is now made to FIG. 9, which illustrates elements of a computer system 910 including a processing unit 920 and computer-readable memory 930 encoded with code 940 that, when executed, causes the computer system to generate a coarse-level topology according to a method herein. In some embodiments, the code 940 may be part of a standalone application, such as an electronic design tool. In some embodiments, the code 940 may be integrated into a larger program that also performs one or more of blocks 210-240 of FIG. 2.

The methods above incorporate an algorithmic approach towards sequentially generating a coarse-level topology of a NoC. In the alternative, a transformer-based machine learning model may be used to sequentially generate a coarse-level NoC topology. A method of generating a NoC topology using the transformer includes providing inputs to the transformer, including specifying a source and destination, and providing all relevant information, such as the encoded state of the NoC so far, physical placements, etc. In response, the transformer transforms the encoded network by suggesting a new connection.

The method further includes determining whether the new connection is valid. The new connection is considered valid if it follows constraints, is deadlock free, etc. If the new connection is valid, it is added to the NoC topology.

If the new connection is not valid, an algorithmic approach may be used to determine a new valid connection (e.g., the method of FIG. 3 or 5). Falling back to an algorithmic approach enables the transformer-based method to remain resilient to any mistakes made by the transformer.

The transformer may be trained on training data including traces of prior topology synthesis, preferably from real designs. The traces describe steps taken, by encoding the intermediate states of a NoC after each connection is routed. The traces may include relevant input information, constraint, physical data, tuning parameters, etc. Randomized runs with various input parameters may be performed to generate a large variety of traces under different kinds of designs. These encoded traces are fed to the transformer during training, causing the transformer to learn to predict the next state of the NoC given its current state. At this stage of training, the transformer is not aware of which choices are good and which choices are bad.

The transformer may then be fine-tuned by having it predict transformations and this time, assign a cost to the predictions (e.g. wire length, route deviation). The fine-tuning teaches the transformer to recognize choices that are good.

Certain methods, which can be implemented in a product, according to the various aspects of the invention may be performed by instructions that are stored upon a non-transitory computer readable medium. The non-transitory computer readable medium stores code including instructions that, if executed by one or more processors, would cause a system or computer to perform steps of the method described herein. The non-transitory computer readable medium includes: a rotating magnetic disk, a rotating optical disk, a flash random access memory (RAM) chip, and other mechanically moving or solid-state storage media. Any type of computer-readable medium is appropriate for storing code comprising instructions according to various example.

Some examples are one or more non-transitory computer readable media arranged to store such instructions for methods described herein. Whatever machine holds non-transitory computer readable media comprising any of the necessary code may implement an example. Some examples may be implemented as: physical devices such as semiconductor chips; hardware description language representations of the logical or functional behavior of such devices; and one or more non-transitory computer readable media arranged to store such hardware description language representations.

Certain examples have been described herein and it will be noted that different combinations of different components from different examples may be possible. Salient features are presented to better explain examples; however, it is clear that certain features may be added, modified and/or omitted without modifying the functional aspects of these examples as described.

Various examples are methods that use the behavior of either or a combination of machines. Method examples are complete wherever in the world most constituent steps occur. For example, IP elements or units include: processors (e.g., CPUs or GPUs), random-access memory (RAM—e.g., off-chip dynamic RAM or DRAM), a network interface for wired or wireless connections such as ethernet, WiFi, 3G, 4G long-term evolution (LTE), 5G, and other wireless interface standard radios. The IP may also include various I/O interface devices, as needed for different peripheral devices such as touch screen sensors, geolocation receivers, microphones, speakers, Bluetooth peripherals, and USB devices, such as keyboards and mice, among others. By executing instructions stored in RAM devices processors perform steps of methods as described herein.

Descriptions herein reciting principles, aspects, and embodiments encompass both structural and functional equivalents thereof. Elements described herein as coupled have an effectual relationship realizable by a direct connection or indirectly with one or more other intervening elements.

Practitioners skilled in the art will recognize many modifications and variations. The modifications and variations include any relevant combination of the disclosed features. Descriptions herein reciting principles, aspects, and embodiments encompass both structural and functional equivalents thereof. Elements described herein as “coupled” or “communicatively coupled” have an effectual relationship realizable by a direct connection or indirect connection, which uses one or more other intervening elements. Embodiments described herein as “communicating” or “in communication with” another device, module, or elements include any form of communication or link and include an effectual relationship. For example, a communication link may be established using a wired connection, wireless protocols, near-filed protocols, or RFID.

To the extent that the terms “including”, “includes”, “having”, “has”, “with”, or variants thereof are used in either the detailed description and the claims, such terms are intended to be inclusive in a similar manner to the term “comprising.”

The scope of the invention, therefore, is not intended to be limited to the exemplary embodiments shown and described herein. Rather, the scope and spirit of present invention is embodied by the appended claims.

What is claimed is:

1. A computer-implemented method of designing a network-on-chip (NoC), the method comprising:
loading a NoC topology;
selecting a source in the NoC topology and identifying multiple destinations to which the source will be connected for communication; and
incrementally adding new connections to the NoC topology, one connection at a time, wherein adding a new connection includes:
selecting a next destination; and
adding to the NoC topology a new valid shortest distance connection between the next destination and an existing connection in the NoC topology.

2. The method of claim 1, wherein the multiple destinations are automatically ordered according to distance from the selected source.

3. The method of claim 1, wherein no lookahead is performed when incrementally adding each new connection.

4. The method of claim 1, wherein lookahead is performed when incrementally adding a new connection.

5. The method of claim 4, wherein incrementally adding the new connections with lookahead includes:
selecting an n^{th} destination;
considering multiple options for routing the selected source to an n+L^{th} destination, wherein L denotes the lookahead;
selecting an option having a shortest valid connection length from the selected source to the n+L^{th} destination; and
adding a new connection to the NoC topology, wherein the new connection is connected to the n^{th} destination per the selected option.

6. The method of claim 1, wherein adding each new connection further includes adding a switch to the NoC topology to connect a new valid shortest distance connection to the existing connection.

7. The method of claim 1, further comprising performing switch and connection reduction on the NoC topology after the new connections have been added.

8. The method of claim 1, wherein the source includes an initiator network interface unit and the multiple destinations include target network interface units.

9. The method of claim 1, further comprising iteratively refining the NoC topology to produce a final NoC topology.

10. A computer system comprising:
a processing unit; and
computer memory encoded with code that, when executed by the processing unit, causes the computer system to:
load a network-on-chip (NoC) topology;
select a source in the NoC topology and identify multiple destinations to which the source will be connected; and
add, incrementally, new connections to the NoC topology, one connection at a time,
wherein adding a new connection includes:
selecting a next destination; and
adding to the NoC topology a new valid shortest distance connection from the next destination to an existing connection in the NoC topology.

11. The computer system of claim 10, wherein lookahead is performed when incrementally adding a new connection.

12. The computer system of claim 11, wherein incrementally adding a new connection with lookahead includes:
selecting an n^{th} destination;
considering multiple options for routing the selected source to an n+L^{th} destination, wherein L denotes the lookahead;
selecting the option having a shortest valid connection length from the selected source to the n+L^{th} destination; and
adding a new connection and switch to topology, wherein the new connection is connected to the n^{th} destination per the selected option.

13. The computer system of claim 10, wherein the code, when executed by the processing unit, further causes the computer system to reduce redundant switches and connections in the NoC topology after the new connections have been incrementally added.

14. The computer system of claim 10, wherein the code, when executed by the processing unit, further causes the computer system to iteratively refine the NoC topology to a final NoC topology.

15. The computer system of claim 10, wherein the code, when executed by the processing unit, further causes the computer system to order the multiple destinations according to distance from the selected source.

16. A product comprising computer-readable memory encoded with code that, when executed, causes the product to:
load a network-on-chip (NoC) topology;
select a source in the NoC topology and identify multiple destinations to which the source will be connected; and
add new connections to the NoC topology, one connection at a time, wherein adding a new connection includes:
selecting a next destination; and
adding to the NoC topology a new valid shortest distance connection from the next destination to an existing connection in the NoC topology.

17. The product of claim 16, wherein lookahead is performed when incrementally adding a new connection.

18. The product of claim 17, wherein incrementally adding a new connection with lookahead includes:
selecting an n^{th} destination;
considering multiple options for routing the selected source to an n+L^{th} destination, wherein L denotes the lookahead;
selecting an option having a shortest valid connection length from the selected source to the n+L^{th} destination; and
adding a new connection to the NoC topology, wherein the new connection connects the selected source to the n^{th} destination per the selected option.

19. The product of claim 16, wherein the code, when executed, further causes the product to reduce redundant switches and connections in the NoC topology after the new connections have been incrementally added.

20. The product of claim 16, wherein the code is part of a NoC design tool.
